(19) United States
(12) Patent Application Publication
(10) Pub. No.: US 2013/0170119 A1
(43) Pub. Date: Jul. 4, 2013

(54) ELECTRONIC APPARATUS

(71) Applicant: PEGATRON CORPORATION, Taipei City (TW)

(72) Inventors: Wei-Chih LAI, Taipei City (TW); Yung-Sheng LEE, Taipei City (TW); Chien-Feng MA, Taipei City (TW); Kuang-Jui CHENG, Taipei City (TW); Tien-Wen LIN, Taipei City (TW)

(73) Assignee: PEGATRON CORPORATION, TAIPEI CITY (TW)

(21) Appl. No.: 13/728,692

(22) Filed: Dec. 27, 2012

(30) Foreign Application Priority Data
Dec. 30, 2011 (TW) 100225103

(51) Int. Cl. H05K 5/02

(52) U.S. Cl. CPC H05K 5/0226
USPC 361/679.02; 361/679.01

(57) ABSTRACT

An electronic apparatus includes a first casing, a second casing, a hinge structure and an elastic structure. The hinge structure is pivotally connected with the first casing and the second casing to open or close the first casing in relative to the second casing. Two ends of the elastic structure are connected with the first casing and the second casing respectively, and disposed adjacent to the hinge structure. The elastic structure supports the first casing when the first casing is opened in relative to the second casing. Otherwise, the elastic structure cushions the first casing when the first casing is closed in relative to the second casing.

### CROSS REFERENCE TO RELATED APPLICATIONS

This Non-provisional application claims priority under 35 U.S.C. §119(a) on Patent Application No(s). 100225103 filed in Taiwan, Republic of China on Dec. 30, 2011, the entire contents of which are hereby incorporated by reference.

### BACKGROUND

1. Technology Field

The present disclosure relates to an electronic apparatus.

2. Related Art

Many commercial electronic apparatuses have a folding design for reducing their dimensions. In more specific, the electronic apparatus is usually configured with a hinge structure for connecting different parts, so that the different parts can be rotated relatively and then folded for easy storage.

In general, the conventional electronic apparatus usually utilizes the hinge structure to connect different casings, so that the casings can be relatively rotated to open/close the electronic apparatus. However, there is no such an auxiliary structure configured to decrease the external force applied to open/close the electronic apparatus, or to cushion the gravity as the electronic apparatus is opened/closed. Accordingly, the user must apply a larger force to open/close a large-sized electronic apparatus. Unfortunately, if the user applies an improper force and does not carefully open/close the electronic apparatus, the casing of the electronic apparatus may be dropped down and damaged.

### SUMMARY

The present disclosure is to provide an electronic apparatus having a structure to support or cushion the casings of the electronic apparatus when the casings is opened or closed.

To achieve the above, an electronic apparatus of the disclosure includes a first casing, a second casing, a hinge structure and an elastic structure. The hinge structure is pivotally connected with the first casing and the second casing to open or close the first casing in relative to the second casing. Two ends of the elastic structure are connected with the first casing and the second casing respectively, and disposed adjacent to the hinge structure. The elastic structure supports the first casing when the first casing is opened in relative to the second casing. Otherwise, the elastic structure cushions the first casing when the first casing is closed in relative to the second casing.

In one embodiment, the elastic structure comprises a pneumatic spring or a hydraulic spring, and the hinge structure is a single-axis hinge structure or a dual-axis hinge structure.

In one embodiment, the electronic apparatus is an all-in-one desktop computer.

As mentioned above, the electronic apparatus of the disclosure is configured with an elastic structure for connecting the first and second casings. Thus, when the user applies a force to open the first casing, the restoring force of the elastic structure can assist the applied force for opening the first casing, so that the user can apply a smaller force to open the first casing. Besides, the restoring force of the elastic structure can also support the first casing. On the contrary, when the user closes the first casing, the resistant force of the elastic structure can cushion the first casing.

These and other features, aspects and advantages of the present disclosure will become better understood with regard to the following description, appended claims, and accompanying drawings.

### BRIEF DESCRIPTION OF THE DRAWINGS

FIG. 1 is a schematic diagram of an electronic apparatus according to an embodiment of the disclosure;

FIGS. 2A and 2B are schematic diagrams showing the closing and opening procedures of the electronic apparatus according to the embodiment of the disclosure; and

FIG. 3 is a schematic diagram showing another aspect of the elastic structure of the electronic apparatus according to the embodiment of the disclosure.

### DETAILED DESCRIPTION OF THE INVENTION

The present invention will be apparent from the following detailed description, which proceeds with reference to the accompanying drawings, wherein the same references relate to the same elements.

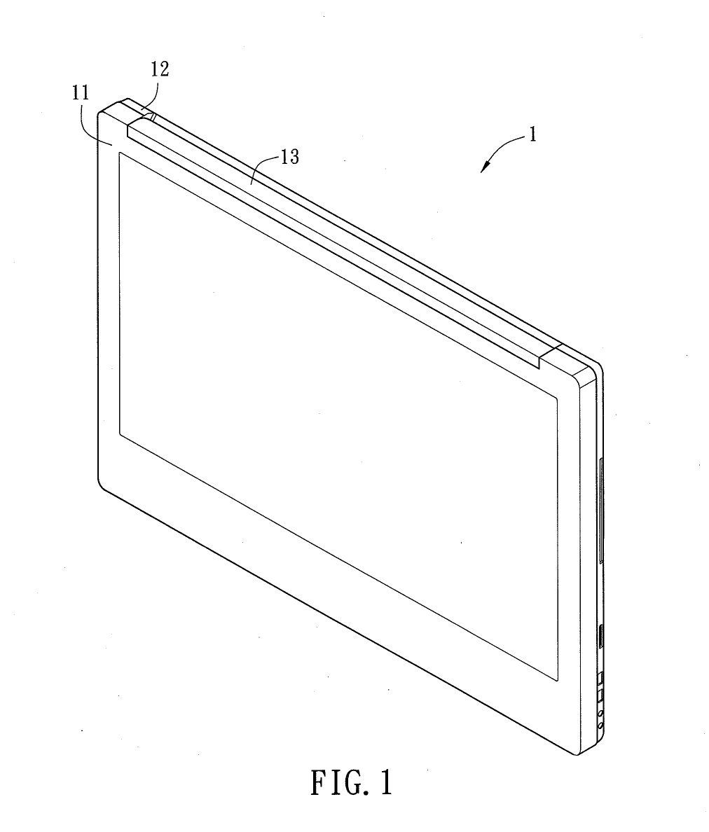

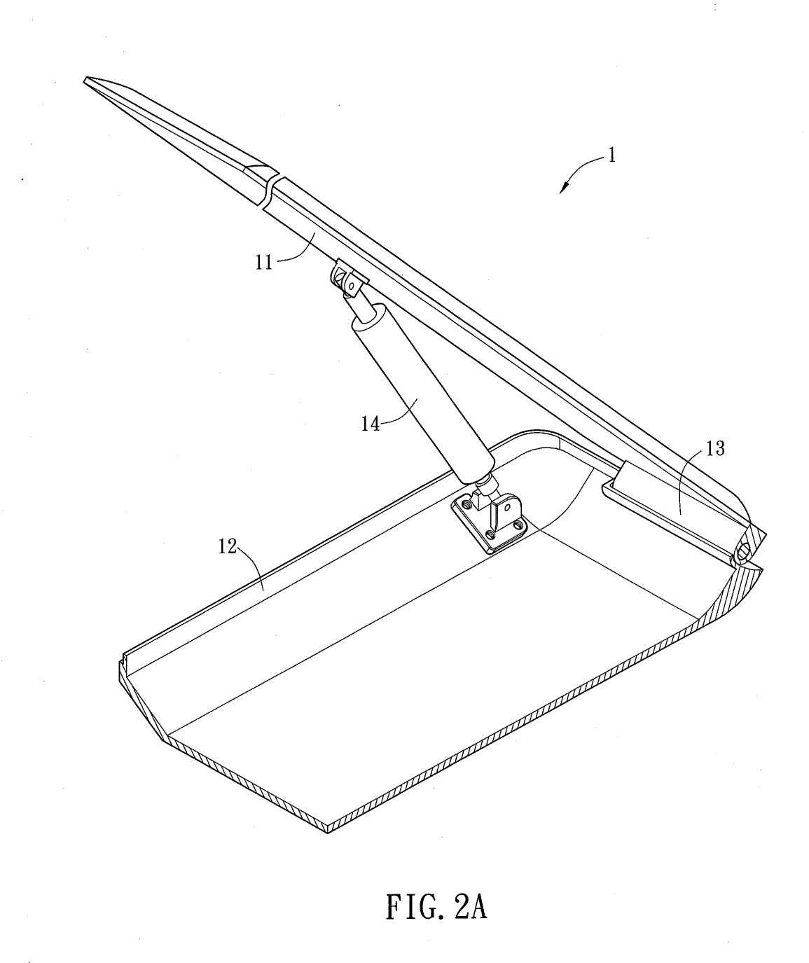

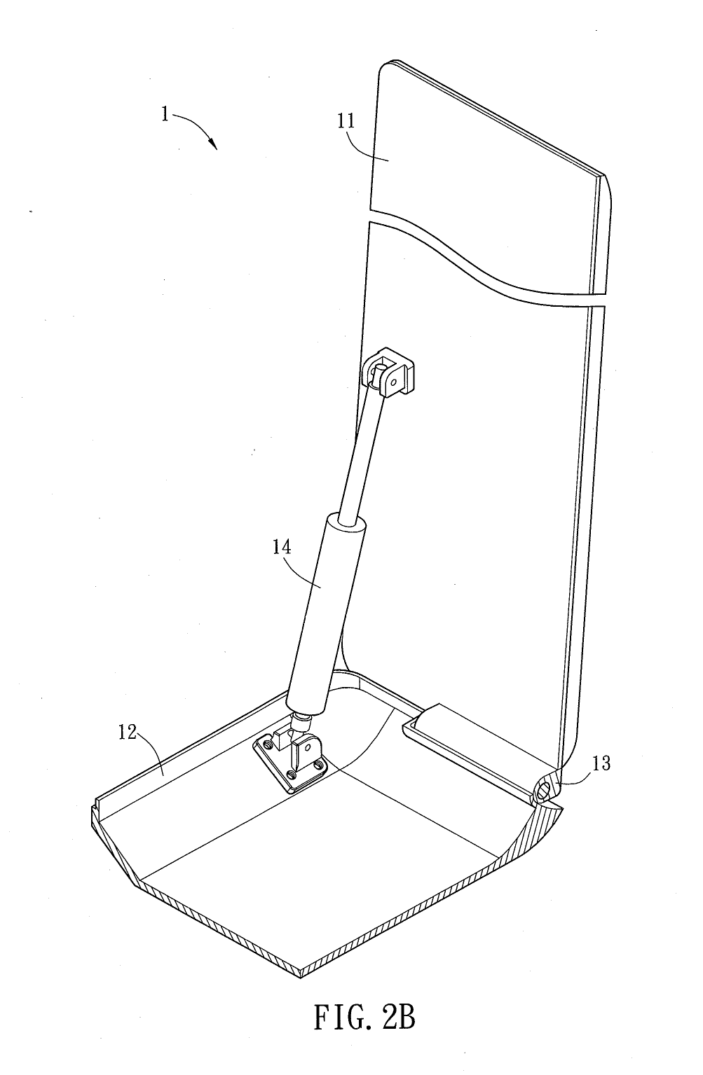

FIG. 1 is a schematic diagram of an electronic apparatus 1 according to an embodiment of the disclosure, and FIGS. 2A and 2B are schematic diagrams showing the closing and opening procedures of the electronic apparatus 1. To be noted, FIGS. 2A and 2B only show parts of the first casing 11 and the second casing 12, and the elastic structure 14 can be configured at, for example but not limited to, one side or two sides of the electronic apparatus 1.

Referring to FIGS. 1, 2A and 2B, the electronic apparatus 1 includes a first casing 11, a second casing 12, a hinge structure 13 and an elastic structure 14. For example, the electronic apparatus 1 is an all-in-one desktop computer, a laptop computer, or any fold-type electronic device. In this embodiment, the electronic apparatus 1 is, for example but not limited to, an all-in-one desktop computer.

With reference to FIG. 2B, the hinge structure 13 is pivotally connected to the first casing 11 and the second casing 12 to open or close the first casing 11 in relative to the second casing 12. Two ends of the elastic structure 14 are connected with the first casing 11 and the second casing 12 respectively, and disposed adjacent to the hinge structure 13. The hinge structure 13 can be a single-axis hinge structure, a dual-axis hinge structure, or other hinge structures. In this embodiment, the hinge structure 13 is, for example but not limited to, a single-axis hinge structure. The elastic structure 14 can be a pneumatic spring, a hydraulic spring, or other types of compressible springs. In this embodiment, the first casing 11 is a front casing configured with a display panel, and the second casing 12 is a rear casing of an all-in-one desktop computer. Otherwise, if necessary, the first casing 11 can be a rear casing while the second casing 12 is a front casing.

The operation of the elastic structure 14 will be described hereinafter with reference to FIGS. 1, 2A and 2B.

As shown in FIG. 1, the first casing 11 is in a close status with respect to the second casing 12. As shown in FIG. 2A, when the user applies a force to open the first casing 11, the first casing 11 is rotated in relative to the second casing 12 through the hinge structure 13. In this case, the elastic structure 14 is released from a compression status. At meanwhile, the restoring force of the elastic structure 14 can assist the applied force, so that the user can apply a smaller force to open the first casing 11.

As shown in FIG. 2B, the user can continuously apply a force to open the first casing 11, or the first casing 11 can be driven by the restoring force of the elastic structure 14 and then automatically rotated to the open status in relative to the second casing 12. Moreover, when the first casing 11 is completely opened with respect to the second casing 12, the elastic structure 14 can support the first casing 11.

On the contrary, when the user applies a force to close the first casing 11, the resistance force as compressing the elastic structure 14 can provide a cushion. That is, the elastic structure 14 can buffer the first casing 11 when the first casing 11 is closed in relative to the second casing 12, thereby preventing the sudden falling of the first casing 11.

Accordingly, the restoring force of the elastic structure 14 of the embodiment can serve as an assistant force for reduce the extra force provided by the user to open the casing 11, and support the first casing 11. On the contrary, when closing the casing 11, the resistance force as compressing the elastic structure 14 can provide a cushion to the first casing 11, which can prevent the sudden falling of the first casing 11 and thus protect the user.

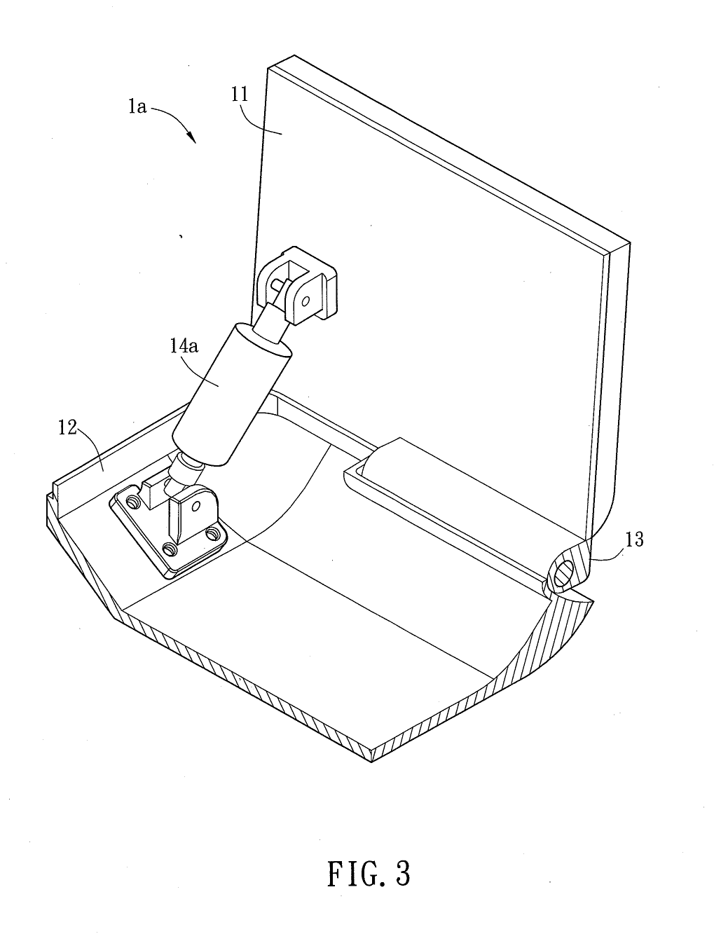

FIG. 3 is a schematic diagram showing another aspect of the elastic structure 14a of the electronic apparatus according to the embodiment of the disclosure. The elastic structure 14a has smaller size and is suitable for the smaller or lighter electronic apparatus 1a. In this case, the elastic structure 14a is connected to the sides of the first casing 11 and the second casing 12. Accordingly, the application scope of the present disclosure can be broadened, and the structure volume can be minimized.

In summary, the electronic apparatus of the disclosure is configured with an elastic structure for connecting the first and second casings. Thus, when the user applies a force to open the first casing, the restoring force of the elastic structure can assist the applied force for opening the first casing, so that the user can apply a smaller force to open the first casing. Besides, the restoring force of the elastic structure can also support the first casing. On the contrary, when the user closes the first casing, the resistant force of the elastic structure can cushion the first casing, thereby preventing the sudden falling of the first casing and thus protecting the user.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. An electronic apparatus, comprising:
a first casing;
a second casing;
a hinge structure pivotally connected with the first casing and the second casing to open or close the first casing in relative to the second casing; and
an elastic structure, wherein two ends of the elastic structure are connected with the first casing and the second casing respectively, and disposed adjacent to the hinge structure;
wherein, the elastic structure supports the first casing when the first casing is opened in relative to the second casing, and the elastic structure cushions the first casing when the first casing is closed in relative to the second casing.

2. The electronic apparatus of claim 1, wherein the elastic structure is a pneumatic spring or a hydraulic spring.

3. The electronic apparatus of claim 1, wherein the hinge structure is a single-axis hinge structure or a dual-axis hinge structure.

4. The electronic apparatus of claim 1, wherein the electronic apparatus is an all-in-one desktop computer.
